(19) United States
(12) Patent Application Publication
(10) Pub. No.: US 2011/0065233 A1
(43) Pub. Date: Mar. 17, 2011

(54) Method for fabricating and repairing organic thin film

(75) Inventors: Jenn-Chang Hwang, Hsinchu (TW); Chung Hwa Wang, Huatan Township (TW); Sheng-Wei Chen, Hsinchu (TW)

(73) Assignee: National Tsing Hua University, Hsinchu (TW)

(21) Appl. No.: 12/656,329

(22) Filed: Jan. 26, 2010

(30) Foreign Application Priority Data
Sep. 16, 2009 (TW) 098131185

(51) Int. Cl. H01L 51/40

(52) U.S. Cl. 438/99; 257/E51.001

(57) ABSTRACT

The present invention relates to a method for fabricating an organic thin film transistor, including: (A) providing a gate electrode; (B) forming a gate insulating layer on the gate electrode; and (C) forming an organic active layer, a source electrode and a drain electrode over the gate insulating layer, and increasing crystallinity of the organic active layer by irradiating the organic active layer. Accordingly, through irradiation, the present invention can efficiently enhance the field effect mobility, and thereby significantly improves the device performance of an organic thin film transistor. Additionally, irradiation mentioned in the present invention also can be used for repairing an organic thin film transistor.

### BACKGROUND OF THE INVENTION

1. Field of the Invention

The present invention relates to a fabricating method and a repairing method of an organic thin film transistor and, more particularly, to a fabricating method and a repairing method of an organic thin film transistor, which can improve device performance.

2. Description of Related Art

Currently, the organic thin film transistors (OTFTs) are the focus of research for flexible electronic applications, because of their low-temperature processing and low manufacturing cost. Pentacene is one of the promising materials for the active layers in OTFTs since it exhibits field effect mobility higher than other organic materials. Regarding the structure of OTFTs, they can be classified into a top-contact type and a bottom-contact type.

With reference to FIG. 1A, there is a cross-sectional view of a conventional top-contact organic thin film transistor. As shown in FIG. 1A, the conventional top-contact organic thin film transistor mainly includes: a gate electrode 11; a gate insulating layer 12 disposed on the gate electrode 11; an organic active layer 13 disposed on the gate insulating layer 12; and a source electrode 14 and a drain electrode 15 disposed on the organic active layer 13, where a channel region C is located between the source electrode 14 and the drain electrode 15. In addition, as shown in FIG. 1B, a conventional bottom-contact organic thin film transistor mainly includes: a gate electrode 11; a gate insulating layer 12 disposed on the gate layer 11; a source electrode 14 and a drain electrode 15 disposed on the gate insulating layer 12, where a channel region C is located between the source electrode 14 and the drain electrode 15; and an organic active layer 13 disposed in the channel region C and on the source electrode 14 and the drain electrode 15.

It was reported that the field effect mobility of OTFTs strongly depends on the crystal orientation and the molecular ordering of pentacene, and the microstructure of pentacene is associated with the deposition temperature. In general, the pentacene film consists of polycrystalline crystallites, mis-oriented molecules, grain boundary and defects, especially deposited at room temperature. Accordingly, in order to enhance the performance of OTFTs, a common step, thermal annealing of about 60° C. to 90° C., is performed after the deposition of pentacene in ultra-high vacuum (UHV) to induce crystallization of mis-oriented molecules, eliminate defects and improve ordering of pentacene molecules.

However, the conventional thermal annealing process has the disadvantage of non-uniform effect. In particular, the device performance may be degraded due to temperature mishandling. Moreover, a severe process condition (i.e. ultra-high vacuum condition) is necessary for the conventional thermal annealing process.

### SUMMARY OF THE INVENTION

The object of the present invention is to provide a method for fabricating an organic thin film transistor to improve crystallinity of an organic active layer via simple and rapid process steps and thereby to significantly enhance the performance of an organic thin film transistor.

To achieve the object, the present invention provides a method for fabricating an organic thin film transistor, including: (A) providing a gate electrode; (B) forming a gate insulating layer on the gate electrode; and (C) forming an organic active layer, a source electrode and a drain electrode over the gate insulating layer, and increasing crystallinity of the organic active layer by irradiating the organic active layer.

Accordingly, in comparison to the conventional thermal annealing process for enhancing crystallinity of an organic active layer, the irradiation process applied in the present invention has none of the prior art disadvantages such as non-uniform effect and degradation of device performance due to temperature mishandling, occurring in the conventional thermal annealing process. In addition, no ultra-high vacuum condition is necessary for the irradiation treatment applied in the present invention, and thus the irradiation treatment is simpler than the conventional thermal annealing process. In particular, in comparison to the conventional thermal annealing process, the method of the present invention can provide an organic thin film transistor with improved performance.

In the method according to the present invention, the organic active layer may be made of any conventional material applied in an organic active layer. Herein, the preferred material of the organic active layer is pentacene owing to its higher mobility.

In the method according to the present invention, preferably, the organic active layer is irradiated by infrared light. Specifically, a quartz tube may be used for providing infrared light that ranges from 2500 nm to 25000 nm in wavelength. Herein, preferably, the organic active layer is irradiated for 15 minutes to 180 minutes.

In detail, in the step (C) of the method according to the present invention, the organic active layer may be first formed, followed by the formation of the source electrode and the drain electrode, so as to fabricate a top-contact organic thin film transistor. That is, the step (C) may include: (C1) forming the organic active layer on the gate insulating layer; and (C2) forming the source electrode and the drain electrode on the organic active layer, and increasing the crystallinity of the organic active layer by irradiating the organic active layer, where a channel region is located between the source electrode and the drain electrode. Herein, in the step (C2), the organic active layer may be first irradiated to enhance its crystallinity and then the source electrode and the drain electrode are formed on the organic active layer. Alternatively, the source electrode and the drain electrode are first formed on the organic active layer and then the organic active layer is irradiated to increase its crystallinity. Additionally, in the step (C) of the method according to the present invention, the source electrode and the drain electrode may be first formed, followed by the formation of the organic active layer, so as to fabricate a bottom-contact organic thin film transistor. That is, the step (C) may include: (C1) forming the source electrode and the drain electrode on the gate insulating layer, wherein a channel region is located between the source electrode and the drain electrode; (C2) forming the organic active layer in the channel region and on the source electrode and the drain electrode; and (C3) increasing the crystallinity of the organic active layer by irradiating the organic active layer.

Besides, the above-mentioned irradiation treatment provided by the present invention also can be applied for repairing an organic thin film transistor so as to improve crystallinity of the organic active layer and thereby significantly enhancing the performance of the organic thin film transistor. Accordingly, the present invention provides a method for repairing an organic thin film transistor, including: irradiating an organic active layer of an organic thin film transistor to increase crystallinity of the organic active layer.

In the method for repairing an organic thin film transistor, the organic thin film transistor may include: a gate electrode; a gate insulating layer, disposed on the gate electrode; and an organic active layer, a source electrode and a drain electrode, disposed over the gate insulating layer. Herein, the organic thin film transistor may be top- or bottom-contact typed. Accordingly, in the organic thin film transistor according to the present invention, the organic active layer may be disposed on the gate insulating layer, and the source electrode and the drain electrode may be disposed on the organic active layer, in which a channel region is located between the source electrode and the drain electrode. Alternatively, the source electrode and the drain electrode are disposed on the gate insulating layer, in which a channel region is located between the source electrode and the drain electrode, and the organic active layer is disposed in the channel region and on the source electrode and the drain electrode.

Other objects, advantages, and novel features of the invention will become more apparent from the following detailed description when taken in conjunction with the accompanying drawings.

### BRIEF DESCRIPTION OF THE DRAWINGS

FIG. 1A shows a cross-sectional view of a conventional top-contact organic thin film transistor;

FIG. 1B shows a cross-sectional view of a conventional bottom-contact organic thin film transistor;

FIGS. 2A to 2C show cross-sectional views for illustrating a fabricating process of a top-contact organic thin film transistor according to a preferred embodiment of the present invention;

FIGS. 2B′ to 2C′ show cross-sectional views for illustrating a fabricating process of a bottom-contact organic thin film transistor according to a preferred embodiment of the present invention;

FIG. 3 shows drain current I_{D} (μA) vs. drain voltage (V) curves according to OTFTs manufactured in Example 4 and Comparative Example 1 at various gate voltages (V_{G}=−20V, −30V and −10V);

FIG. 4 shows [drain current I_{D} (μA)] ^{1/2} vs. gate voltage (V) curves according to OTFTs manufactured in Example 4 and Comparative Example 1 at a drain voltage V_{D} of −40V;

FIG. 5 shows field effect mobility & maximum drain current vs. irradiation time curves, in which -▪- shows a field effect mobility vs. irradiation time curve, and -◯- shows a maximum drain current vs. irradiation time curve;

FIG. 6 shows XRD data according to Examples 3, 5 and 6 and Comparative Example 1;

FIG. 7 shows [(001) peak intensity I_{IR}/(001) peak intensity with no irradiation I_{A}] & full width at half maximum (FWHM) vs. irradiation time curves; and

FIG. 8 shows [peak area A/peak area with no irradiation A₀] vs. irradiation time curves, in which -◯- curve means the crystal I (2θ=5.91°), and -▪- curve means the crystal II (2θ=5.84°).

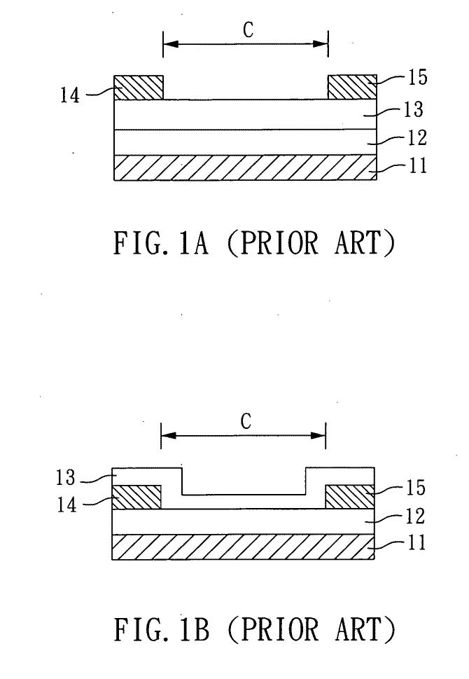

### DETAILED DESCRIPTION OF THE PREFERRED EMBODIMENT

### Examples 1-6 and Comparative Example 1

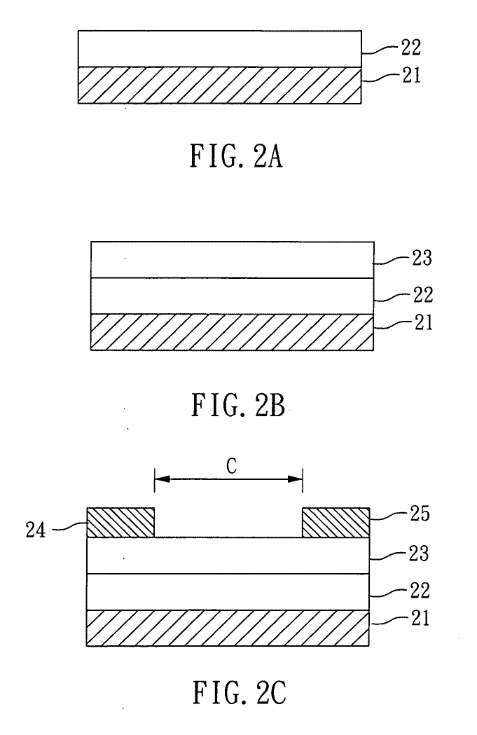

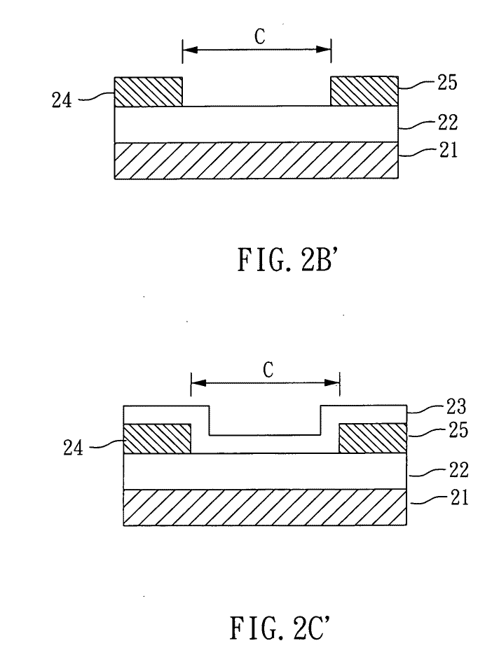

With reference to FIGS. 2A to 2C, there are cross-sectional views for illustrating a fabricating process of a top-contact organic thin film transistor according to the present invention.

As shown in FIG. 2A, a gate electrode 21 is provided and a gate insulating layer 22 (its thickness is 100 nm and its material is silicon dioxide) is formed on the gate electrode 21 by means of dry oxidation. Herein, the gate electrode 21 used in the present invention is a heavily doped Si (100) substrate. Subsequently, the gate insulating layer 22/the gate electrode 21 is cleaned by successive ultrasonic treatments with de-ionized water, acetone, hot trichloroethylene, acetobe, HNO₃, methyl alcohol and de-ionized water in order, and then blown with dry nitrogen.

Next, as shown in FIG. 2B, through thermal evaporation, an organic active layer 23 (its thickness is 70 nm) is deposited on the gate insulating layer 22 at a pressure of 2×10⁻⁶torr. The deposition rate is maintained at 0.5 Å/s and monitored by a quartz crystal oscillator. Herein, the organic active layer 23 of the present invention is made of pentacene.

Finally, as shown in FIG. 2C, through a shadow mask, 70 nm-thick Au pads are deposited on the organic active layer 23 as the source electrode 24 and the drain electrode 25. Herein, there is a channel region C between the source electrode 24 and the drain electrode 25, and the thickness and the length of the channel region C are defined as 1000 μm and 100 μm, respectively. Then, samples are annealed respectively for 15 minutes (Example 1), 30 minutes (Example 2), 60 minutes (Example 3), 90 minutes (Example 4), 120 minutes (Example 5) and 180 minutes (Example 6) with a quartz tube of 2500-25000 nm in wavelength shining onto the channel region C at 50 Watts in the vacuum of 5×10⁻³ torr. Meanwhile, in Comparative Example 1, the channel region C is not irradiated by infrared light.

In addition, the present invention also provides a method for fabricating a bottom-contact organic thin film transistor.

As shown in FIG. 2B′, after the gate insulating layer 22 is formed on the gate electrode 21 through the aforementioned steps, a source electrode 24 and a drain electrode 25 are formed on the gate insulating layer 22. Herein, there is a channel region C between the source electrode 24 and the drain electrode 25.

Finally, as shown in FIG. 2C′, an organic active layer 23 is formed in the channel region C and on the source electrode 24 and the drain electrode 25, so as to obtain a bottom-contact organic thin film transistor. Next, the crystallinity of the organic active layer 23 is enhanced by infrared irradiation.

### Current-Voltage Characteristics Analysis

The current-voltage characteristics of OTFTs are measured by using Agilent 4155C and Agilent 4284 analyzers.

[symbol]

Drain Current vs. Drain Voltage

[symbol]

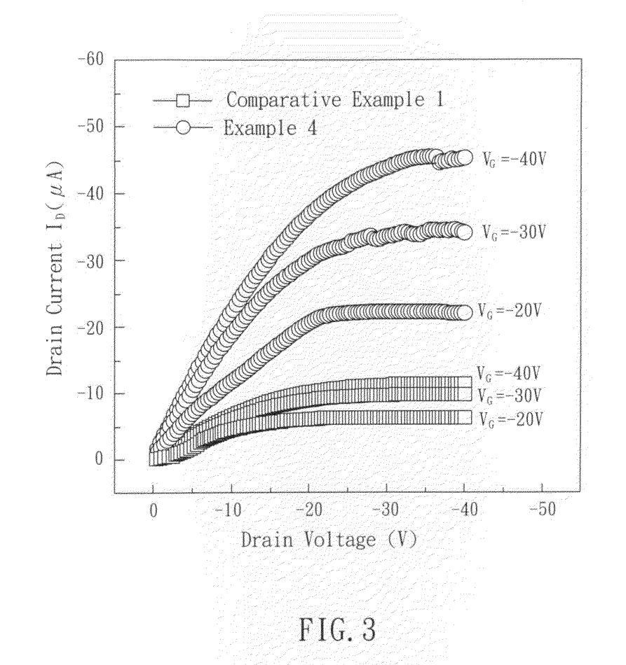

FIG. 3 shows drain current I_{D} (μA) vs. drain voltage (V) curves according to OTFTs manufactured in Example 4 and Comparative Example 1 at various gate voltages (V_{G}=−20V, −30V and −10V). These curves shown in FIG. 3 suggest that the drain current according to Example 4 (-◯-, infrared irradiation for 90 minutes) is significantly higher than that according to Comparative Example 1 (-□-, no infrared irradiation) at the same drain voltage and gate voltage. Also, the maximum drain current according to Example 4 is significantly higher than that according to Comparative Example 1. For example, in the case of setting the gate voltage at −40V, the maximum drain current according to Example 4 is 4.91×10⁻⁵ A, while the maximum drain current according to Comparative Example 1 is 1.14×10⁻⁵ A. This suggests that the resistance of the organic active layer is reduced after infrared irradiation.

[symbol]

Drain Current vs. Gate Voltage

[symbol]

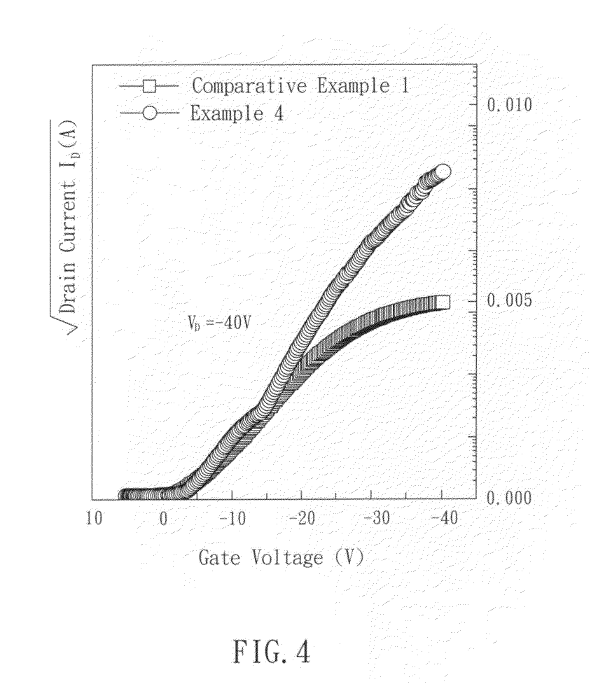

FIG. 4 shows [drain current I_{D} (μA)]^{1/2} vs. gate voltage (V) curves according to OTFTs manufactured in Example 4 and Comparative Example 1. These curves shown in FIG. 4 suggest that the drain current according to Example 4 (-◯-, infrared irradiation for 90 minutes) is higher than that according to Comparative Example 1 (-□-, no infrared irradiation) at the same drain voltage and gate voltage. Herein, the field effect mobility (μ_{FE}) and the threshold voltage are extracted by the slope and the intercept of curves, respectively.

[symbol]

Field Effect Mobility & Maximum Drain Current vs. Irradiation Time

[symbol]

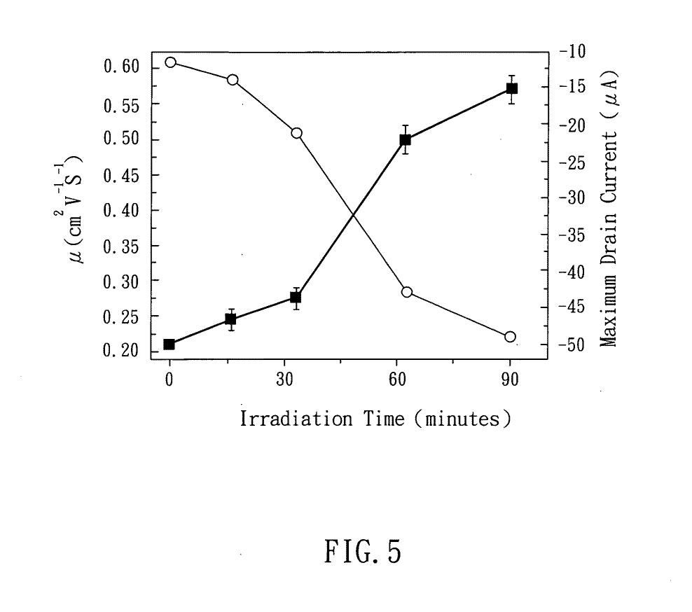

With reference to FIG. 5, -▪- shows a field effect mobility vs. irradiation time curve, and -◯- shows a maximum drain current vs. irradiation time curve. FIG. 5 suggests that the field effect mobility increases from 0.21 cm²/Vs (no infrared irradiation) to 0.59 cm²/Vs (infrared irradiation for 90 minutes), and the maximum drain current is enhanced as irradiation time increases. In general, the value of field effect mobility varies from device to device. Thereby, in FIG. 5, the variation is expressed by the error bar estimated from the device characteristics of 3-5 different OTFTs under the same fabrication condition.

The increase of field effect mobility implies the possible scattering mechanisms in the organic active layer are eliminated. Horowitz et al. reported that the density of grain boundaries in the pentacene organic film is closely correlated to the field effect mobility. Accordingly, it can be inferred from these experiment results that the increase of field effect mobility probably results from the reduction of grain boundaries in the pentacene film after infrared irradiation. However, the reduction of other possible defects (such as mis-oriented molecules) cannot be excluded since they may play roles in increasing the field effect mobility.

### X-Ray Diffraction (XRD) Analysis

The XRD analysis is performed on a diffractometer (Shimadzu XRD-6000) with monochromated CuKα radiation (λ=1.54 Å) to extract the crystalline information of the organic active layer.

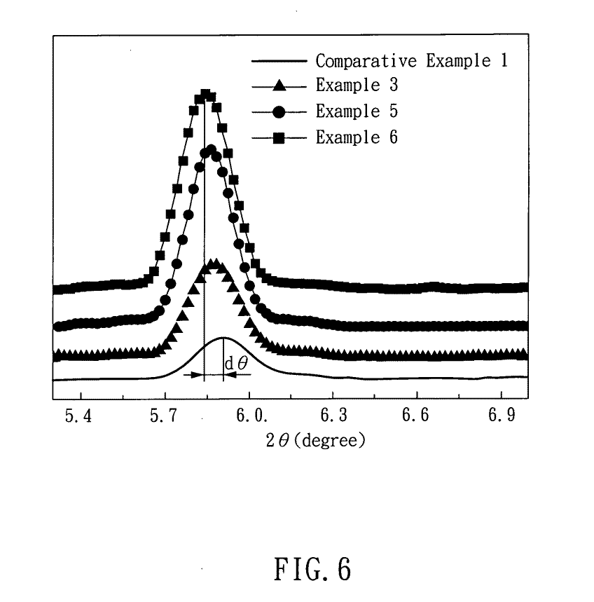

FIG. 6 shows the results of XRD analysis according to Examples 3, 5 and 6 and Comparative Example 1. It was reported that the signal of the pentacene “bulk” phase (i.e. 2θ=6.15°) does not appear until the pentacene film is thicker than 70 nm (determined by a quartz oscillator). Accordingly, as shown in FIG. 6, the (001) peak of the pentacene “thin film” phase (i.e. 2θ=5.9°) is observed and no (001) peak of the pentacene “bulk” phase (i.e. 2θ=6.15°) appears. In addition, after infrared irradiation for 3 hours, the intensity of the (001) peak increases and the (001) peak slightly shifts from 2θ=5.9° to 2θ=5.84°, as shown in FIG. 6. This indicates that infrared irradiation induces the crystal re-orientation of pentacene and the enlargement of crystallinity.

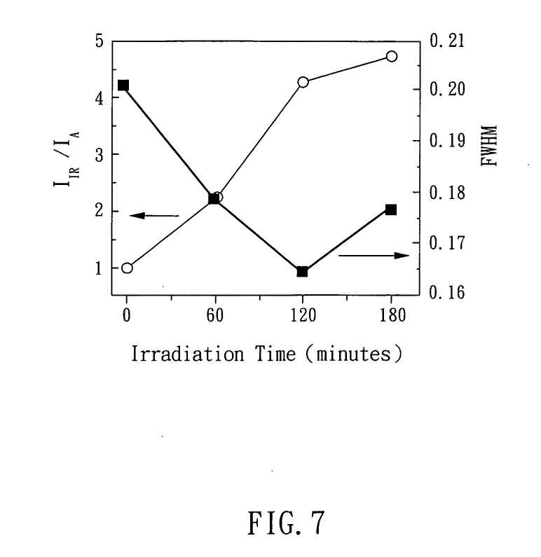

FIG. 7 shows [(001) peak intensity I_{IR}/(001) peak intensity with no irradiation I_{A}] & full width at half maximum (FWHM) vs. irradiation time curves. In view of FIG. 7, it can be confirmed that the (001) peak of the pentacene thin film phase increases in intensity by 4.5 times after infrared irradiation at 50 watts for 2 hours (Example 5), accompanied with the reduction of the full width at half maximum (FWHM) from 0.20 to 0.16.

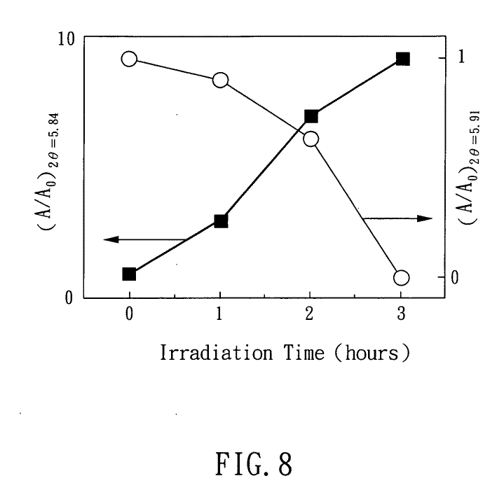

Besides, in the curve-fitting, it can be found that the organic active layer (i.e. the pentacene film) of the present invention has two types of crystal orientations, i.e. crystal I (2θ=5.91°) and crystal II (2θ=5.84°). FIG. 8 shows [peak area A/peak area with no irradiation A₀] vs. irradiation time curves. In FIG. 8, -◯- curve means the crystal I (2θ=5.91°), and -▪- curve means the crystal II (2θ=5.84°).

As shown in FIG. 8, the crystal I reduces rapidly and the crystal II increases abruptly with infrared time. A complete transformation from the crystal I to the crystal II is achieved after infrared irradiation for 180 minutes. However, the increase amount of the crystal II is much larger than that of the crystal I. This supports that some amount of the crystal II results from the recrystallization of mis-oriented pentacene molecules. It can be deduced from the XRD data that the infrared light can induce vibration of pentacene molecules, and thereby re-orientation of pentacene crystal and the crystallization of mis-oriented pentacene occur. Accordingly, it can be known that a larger grain of pentacene exhibits higher field effect mobility and higher maximum drain current and thereby the device performance is enhanced.

In the present invention, the grain of the organic active layer is enhanced by irradiation, and thereby the field effect mobility of the organic tin film transistor increases and its device performance is improved. In comparison to conventional thermal annealing process, the irradiation process applied in the present invention is simpler and faster. In particular, the irradiation process applied in the present invention has no disadvantage of non-uniform effect occurring in the conventional thermal annealing process, and thereby can significantly improve the device performance.

Although the present invention has been explained in relation to its preferred embodiment, it is to be understood that many other possible modifications and variations can be made without departing from the scope of the invention as hereinafter claimed.

What is claimed is:

1. A method for fabricating an organic thin film transistor, comprising:
(A) providing a gate electrode;
(B) forming a gate insulating layer on the gate electrode; and
(C) forming an organic active layer, a source electrode and a drain electrode over the gate insulating layer, and increasing crystallinity of the organic active layer by irradiating the organic active layer.

2. The method as claimed in claim 1, wherein the organic active layer is made of pentacene.

3. The method as claimed in claim 1, wherein the organic active layer is irradiated by infrared light.

4. The method as claimed in claim 1, wherein the step (C) comprises:
(C1) forming the organic active layer on the gate insulating layer; and
(C2) forming the source electrode and the drain electrode on the organic active layer, and increasing the crystallinity of the organic active layer by irradiating the organic active layer, wherein a channel region is located between the source electrode and the drain electrode.

5. The method as claimed in claim 4, wherein in the step (C2), the organic active layer is first irradiated to increase its crystallinity and then the source electrode and the drain electrode are formed on the organic active layer.

6. The method as claimed in claim 4, wherein in the step (C2), the source electrode and the drain electrode are first formed on the organic active layer and then the organic active layer is irradiated to increase its crystallinity.

7. The method as claimed in claim 1, wherein the step (C) comprises:
(C1) forming the source electrode and the drain electrode on the gate insulating layer, wherein a channel region is located between the source electrode and the drain electrode;
(C2) forming the organic active layer in the channel region and on the source electrode and the drain electrode; and
(C3) increasing the crystallinity of the organic active layer by irradiating the organic active layer.

8. The method as claimed in claim 1, wherein the organic active layer is irradiated for 15 minutes to 180 minutes.

9. The method as claimed in claim 3, wherein the infrared light ranges from 2500 nm to 25000 nm in its wavelength.

10. The method as claimed in claim 3, wherein the infrared light is provided from a quartz tube.

11. A method for repairing an organic thin film transistor, comprising:
irradiating an organic active layer of an organic thin film transistor to increase crystallinity of the organic active layer.

12. The method as claimed in claim 11, wherein the organic active layer is made of pentacene.

13. The method as claimed in claim 11, wherein the organic active layer is irradiated by infrared light.

14. The method as claimed in claim 11, wherein the organic thin film transistor comprises:
a gate electrode;
a gate insulating layer, disposed on the gate electrode; and
the organic active layer, a source electrode and a drain electrode, disposed over the gate insulating layer.

15. The method as claimed in claim 14, wherein the organic active layer is disposed on the gate insulating layer, the source electrode and the drain electrode are disposed on the organic active layer, and a channel region is located between the source electrode and the drain electrode.

16. The method as claimed in claim 14, wherein the source electrode and the drain electrode are disposed on the gate insulating layer, a channel region is located between the source electrode and the drain electrode, and the organic active layer is disposed in the channel region and on the source electrode and the drain electrode.

17. The method as claimed in claim 11, wherein the organic active layer is irradiated for 15 minutes to 180 minutes.

18. The method as claimed in claim 13, wherein the infrared light ranges from 2500 nm to 25000 nm in its wavelength.

19. The method as claimed in claim 13, wherein the infrared light is provided from a quartz tube.
